(19) United States
(12) Patent Application Publication
(10) Pub. No.: US 2019/0157237 A1
(43) Pub. Date: May 23, 2019

(54) SEMICONDUCTOR DEVICES HAVING WIRE BONDING STRUCTURES AND METHODS OF FABRICATING THE SAME

(71) Applicant: SAMSUNG ELECTRONICS CO., LTD., Suwon-si (KR)

(72) Inventors: Yong Je LEE, Hwaseong-si (KR); Seunglo LEE, Asan-si (KR); Sungil CHO, Asan-si (KR); Hosoo HAN, Asan-si (KR)

(73) Assignee: SAMSUNG ELECTRONICS CO., LTD., Suwon-si (KR)

(21) Appl. No.: 16/057,323

(22) Filed: Aug. 7, 2018

(30) Foreign Application Priority Data
Nov. 20, 2017 (KR) 10-2017-0155161

(51) Int. Cl. H01L 23/00

(52) U.S. Cl. CPC H01L 24/48; H01L 24/49; H01L 2224/48145; H01L 2224/48227; H01L 2224/48465; H01L 2224/4912; H01L 2224/85986; H01L 2224/04042; H01L 2224/48147; H01L 24/04; H01L 24/85; H01L 2224/8503; H01L 2224/85201; H01L 2224/48091

(57) ABSTRACT

A semiconductor device includes a first device having a first pad; a second device having a second pad; and a bonding wire electrically connecting the first device and the second device to each other via the first pad and the second pad. The bonding wire includes: a first bonding structure provided at a first end of the bonding wire, electrically connected to the first device and includes: a first ball bonding region; and a first stitch bonding region; and a second bonding structure provided at a second end opposite of the first end of the bonding wire and electrically connected to the second device.

### CROSS-REFERENCE TO RELATED APPLICATION

This U.S. non-provisional patent application claims priority from Korean Patent Application No. 10-2017-0155161 filed on Nov. 20, 2017, the entire contents of which are hereby incorporated by reference.

### BACKGROUND

Apparatuses and methods consistent with example embodiments relate to a semiconductor, and more particularly, to a semiconductor device having a wire bonding structure and a method of fabricating the same.

Various bonding techniques are developed to electrically connect leads or bonding pads of semiconductor devices to leads or bonding pads of other electrical apparatuses such as a semiconductor device, a printed circuit board, or an interposer. A wire bonding technique is one of those bonding techniques. The adhesion of the wire bonding is an essential factor in electrical and mechanical durability of semiconductor products.

### SUMMARY

One or more example embodiments of inventive concepts provide a semiconductor device having an electrically and mechanically enhanced wire bonding structure and a method of fabricating the same.

One or more example embodiments of inventive concepts provide a semiconductor device having a wire bonding structure with an improved adhesion and a method of fabricating the same.

One or more example embodiments of inventive concepts provide a semiconductor device having a wire bonding structure and a method of fabricating the same in which a stitch bonding is added in addition to a ball bonding so that bonding wires secure reliability in electrical connection even when the bonding wires are broken during a wire bonding process.

According to an aspect of an example embodiment of inventive concepts, a semiconductor device may include: a first device having a first bonding pad; a second device having a second bonding pad; and a bonding wire electrically connecting the first device and the second device to each other. The bonding wire may include: a first bonding structure electrically connected to the first device and having a ball bonding region and a stitch bonding region; and a second bonding structure electrically connected to the second device and different from the first bonding structure.

According to an aspect of an another example embodiment of inventive concepts, a semiconductor device may include: a substrate including a substrate pad; a semiconductor chip mounted on the substrate and including a chip pad; and a bonding wire having one end connected to the substrate pad and an opposite end connected to the chip pad. The one end of the bonding wire may include a substrate bonding structure. The substrate bonding structure may include: a ball bonding region in which a conductive ball is connected to the substrate pad; and a stitch bonding region in which the bonding wire extends from the conductive ball and is partially inserted into the substrate pad. The opposite end of the bonding wire may include a chip bonding structure in which the bonding wire extends from the stitch bonding region to come into electrical connection with the chip pad.

According to an aspect of another example embodiment of inventive concepts, a method of fabricating a semiconductor device may include: mounting a semiconductor chip having a chip pad on a substrate having a substrate pad; and forming a bonding wire extending from the substrate pad toward the chip pad, the bonding wire having a substrate bonding structure in which one end of the bonding wire is coupled to the substrate pad and a chip bonding structure in which an opposite end of the bonding wire is coupled to the chip pad. The step of forming the bonding wire may include: forming the substrate bonding structure including: a ball boding region in which a conductive ball is bonded to the substrate pad; and a stitch bonding region in which a conductive wire extends from the conductive ball and is connected to the substrate pad; extending the conductive wire from the stitch bonding region toward the chip pad; and connecting the conductive wire to the chip pad to form the chip bonding structure.

According to an aspect of another example embodiment of inventive concepts, a semiconductor device may include: a first device having a first pad; a second device having a second pad; and a bonding wire electrically connecting the first device and the second device to each other via the first pad and the second pad. The bonding wire may include: a first bonding structure provided at a first end of the bonding wire, electrically connected to the first device and includes: a first ball bonding region; and a first stitch bonding region; and a second bonding structure provided at a second end opposite of the first end of the bonding wire and electrically connected to the second device.

According to an aspect of another example embodiment of inventive concepts, a semiconductor device may include: a substrate including a substrate pad; a semiconductor chip mounted on the substrate and including a chip pad; and a bonding wire having a first end being connected to the substrate pad and a second end opposite to the first end being connected to the chip pad. The first end of the bonding wire includes a substrate bonding structure, the substrate bonding structure including: a first ball bonding region in which a first conductive ball is connected to the substrate pad; and a first stitch bonding region in which the bonding wire extends from the first conductive ball and is partially inserted into the substrate pad. The second end of the bonding wire may include a chip bonding structure in which the bonding wire extends from the first stitch bonding region to come into electrical connection with the chip pad.

According to an aspect of another example embodiment of inventive concepts, a semiconductor device may include: a substrate including a first pad provided on the substrate; a chip provided on the substrate having a second pad provided on the chip; and a bonding wire connecting the substrate and the chip to each other via the first pad and the second pad. The bonding wire may include: a first bonding portion provided at a first end of the bonding wire to the substrate and including: a first bonding region; and a second bonding region; and a second bonding portion provided at a second end opposite of the first end of the bonding wire and electrically connected to the chip. In the first bonding region, the bonding wire may be ball-bonded to the substrate, and in the second bonding region, the bonding wire may be stitched to the substrate.

According to an aspect of another example embodiment of inventive concepts, a method of fabricating a semiconductor device may include: mounting a semiconductor chip having a chip pad on a substrate having a substrate pad; and forming a bonding wire extending from the substrate pad toward the chip pad, the bonding wire including: a substrate bonding structure in which a first end of the bonding wire is coupled to the substrate pad; and a chip bonding structure in which a second end opposite to the first end of the bonding wire is coupled to the chip pad. Forming the bonding wire may include: forming the substrate bonding structure including: a first ball bonding region in which a first conductive ball, as a first portion of the bonding wire, is bonded to the substrate pad; and a first stitch bonding region in which a conductive wire, as a second portion of the bonding wire, extends from the first conductive ball and is connected to the substrate pad; extending the conductive wire from the first stitch bonding region toward the chip pad; and connecting the conductive wire to the chip pad to form the chip bonding structure.

### BRIEF DESCRIPTION OF THE DRAWINGS

FIG. 1A illustrates a cross-sectional view showing a semiconductor device according to an example embodiment.

FIG. 1B illustrates a cross-sectional view showing a semiconductor device according to an example embodiment.

FIGS. 2A to 2C illustrate cross-sectional views showing a first bonding structure of the semiconductor device depicted in FIG. 1A.

FIGS. 3A and 3B illustrate cross-sectional views showing warpage of a first bonding structure of the semiconductor device depicted in FIG. 1A.

FIGS. 4A to 4C illustrate cross-sectional views showing a first bonding structure of the semiconductor device depicted in FIG. 1B.

FIGS. 5A and 5B illustrate cross-sectional views showing warpage of a first bonding structure of the semiconductor device depicted in FIG. 1B.

FIG. 6A illustrates a cross-sectional view showing a second bonding structure of the semiconductor device depicted in FIG. 1A.

FIG. 6B illustrates a cross-sectional view showing a second bonding structure of the semiconductor device depicted in FIG. 1B.

FIGS. 7A and 7B illustrate cross-sectional views showing a semiconductor multichip package according to example embodiments.

FIGS. 8A to 8H illustrate cross-sectional views showing a method of fabricating a semiconductor device according to example embodiments.

FIGS. 9A to 9D illustrate cross-sectional views showing a method of fabricating a semiconductor device according to example embodiments.

FIGS. 10A to 10G illustrate cross-sectional views showing a method of fabricating a semiconductor device according to example embodiments.

### DETAILED DESCRIPTION

Hereinafter, it will be described in detail a semiconductor device having a wire bonding structure and a method of fabricating the same according to exemplary embodiments of inventive concepts in conjunction with the accompanying drawings.

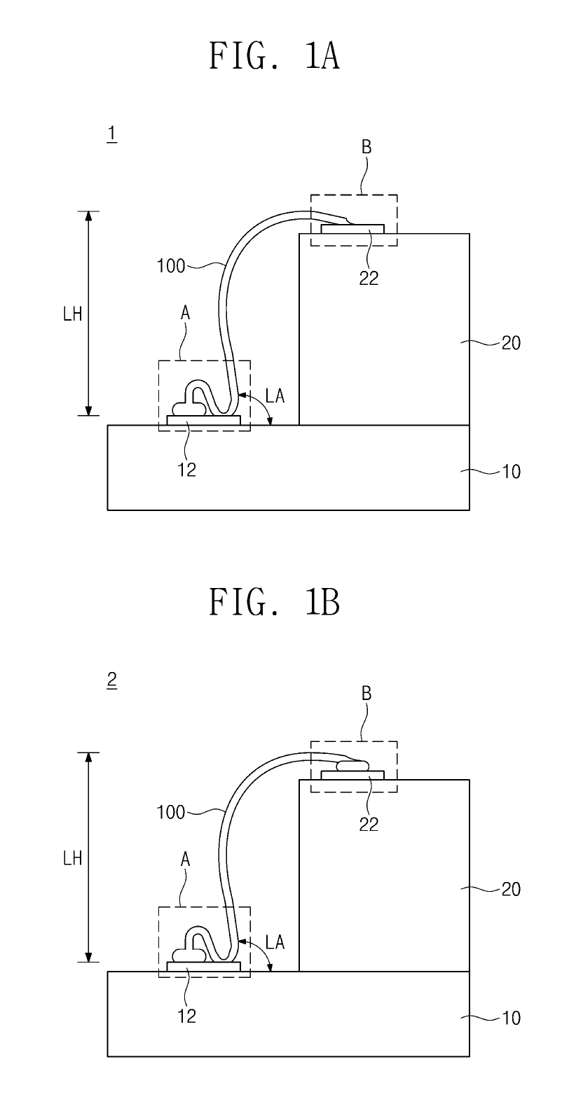

FIG. 1A illustrates a cross-sectional view showing a semiconductor device 1 according to an example embodiment. FIG. 1B illustrates a cross-sectional view showing a semiconductor device 2 according to an example embodiment.

Referring to FIG. 1A, a semiconductor device 1 may include a first device 10 and a second device 20 that are electrically connected to each other through a bonding wire 100. The first device 10 may include a first bonding pad 12 coupled to the bonding wire 100, and the second device 20 may include a second bonding pad 22 coupled to the bonding wire 100. The second device 20 may be provided on the first device 10 in such a way that the first pad 12 is not covered with the second device 20. That is, the first bonding pad 12 is exposed without being covered by the second device 20. Alternatively, the first and second devices 10 and 20 may be provided vertically spaced apart from each other. Alternatively, the first and second devices 10 and 20 may be provided laterally spaced apart from each other at the same level or at different levels.

One of the first and second devices 10 and 20 may include a semiconductor chip, and the other of the first and second devices 10 and 20 may include a printed circuit board or an interposer. Alternatively, the first and second devices 10 and 20 may include the same or different types of semiconductor chips.

In an example embodiment, the semiconductor device 1 may be or include a semiconductor package. For example, the first device 10 may be a package substrate such as a printed circuit board (PCB), and the second device 20 may be a semiconductor chip such as a memory chip, a logic chip, or a combination thereof. Hereinafter, for convenience of description, the first device 10 is also called a package substrate and the first bonding pad 12 is also called a substrate pad Likewise, the second device 20 is also called a semiconductor chip and the second bonding pad 22 is also called a chip pad.

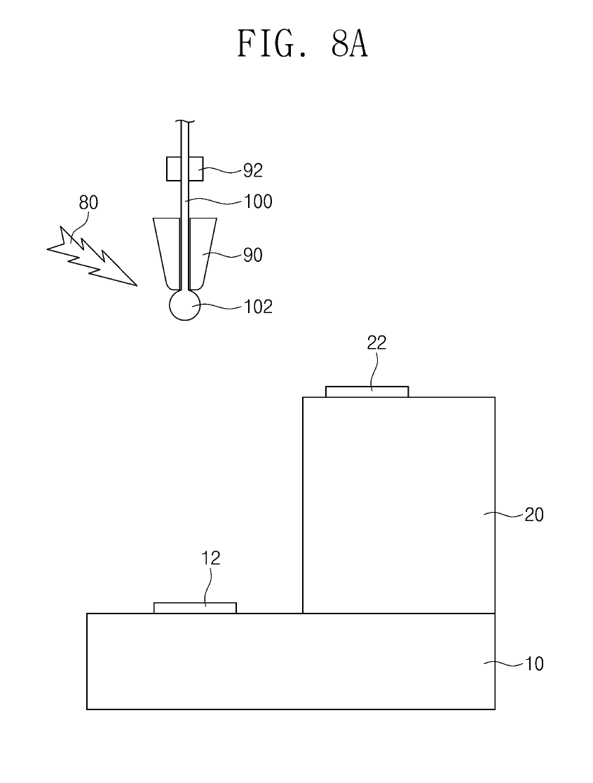

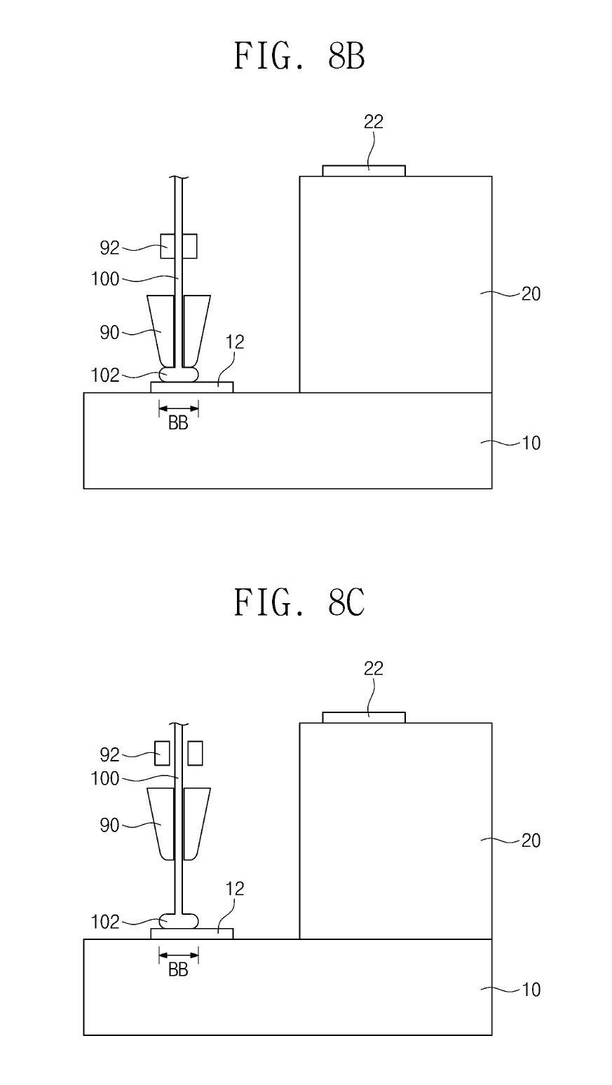

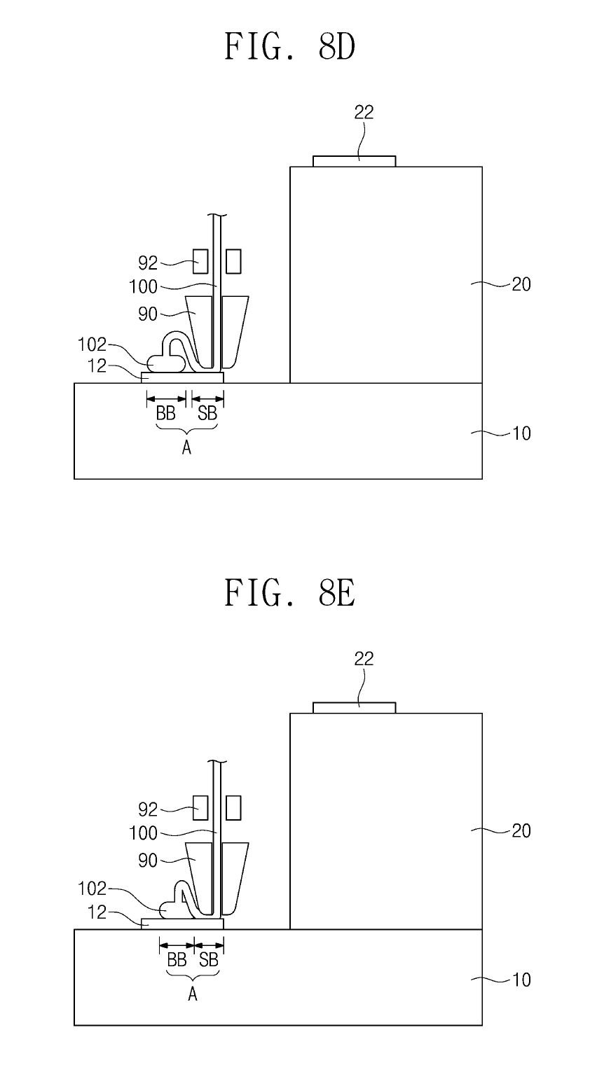

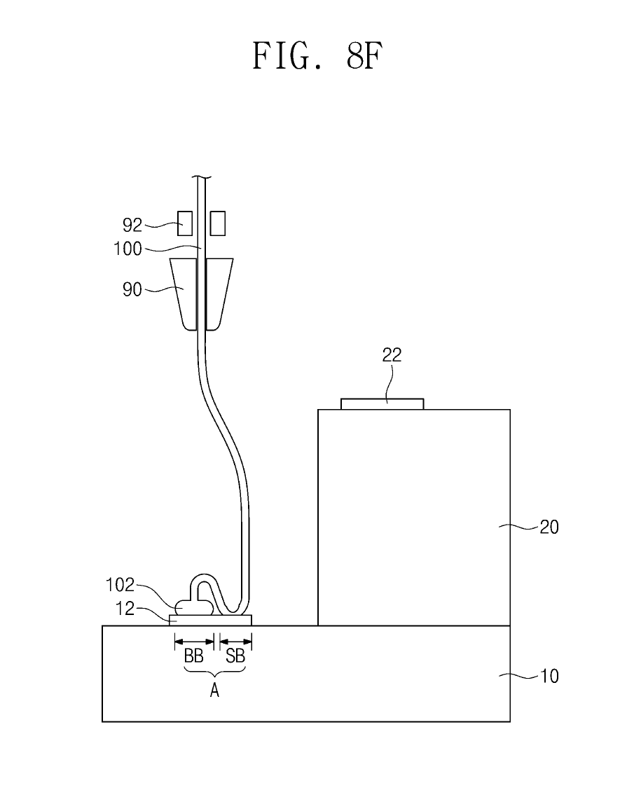

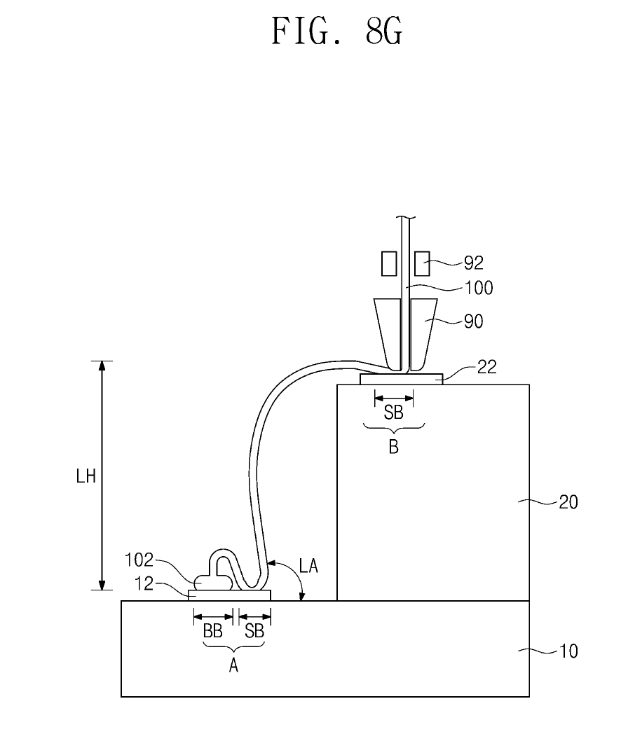

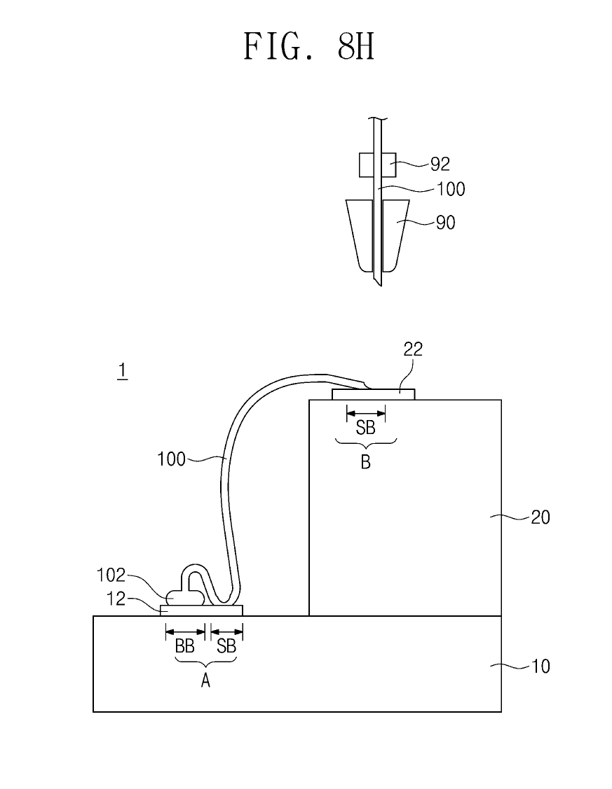

The bonding wire 100 may be coupled to the substrate pad 12 to form a first bonding structure A and also coupled to the chip pad 22 to form a second bonding structure B different from the first bonding structure A. The bonding wire 100 may be obtained in a reverse loop mode in which the bonding wire 100 is formed along a direction from the substrate pad 12 at a lower level toward the chip pad 22 at a higher level, as discussed below with reference to FIGS. 8A to 8H. The bonding wire 100 may not be limited in loop angle LA and loop height LH. This feature will be discussed in detail later.

Referring to FIG. 1B, a semiconductor device 2 may be configured identically or similarly to the semiconductor device 1 of FIG. 1A. For example, the semiconductor device 2 may include a package substrate 10 having a substrate pad 12, and a semiconductor chip 20 mounted on the package substrate 10 and having a chip pad 22, and a bonding wire 100 provided between the substrate pad 12 and the chip pad 22 and electrically connecting the package substrate 10 and the semiconductor chip 20 to each other.

Similar to the semiconductor device 1 of FIG. 1A, the bonding wire 100 of the semiconductor device 2 may be coupled to the substrate pad 12 to form a first bonding structure A and also coupled to the chip pad 22 to form a second bonding structure B different from the first bonding structure A. The second bonding structure B of the semiconductor device 2 may be different from the second bonding structure B of the semiconductor device 1.

In this description, the first bonding structure A may indicate a substrate bonding structure, or an electrical connection structure between the bonding wire 100 and the package substrate 10. Likewise, the second bonding structure B may indicate a chip bonding structure, or an electrical connection structure between the bonding wire 100 and the semiconductor chip 20.

The first bonding structure A and the second bonding structure B will be discussed below. In the example embodiments that follow, unless otherwise explicitly stated, a description about the first bonding structure A of the semiconductor device 1 in FIG. 1A may be identically or similarly applicable to the first bonding structure A of the semiconductor device 2 in FIG. 1B.

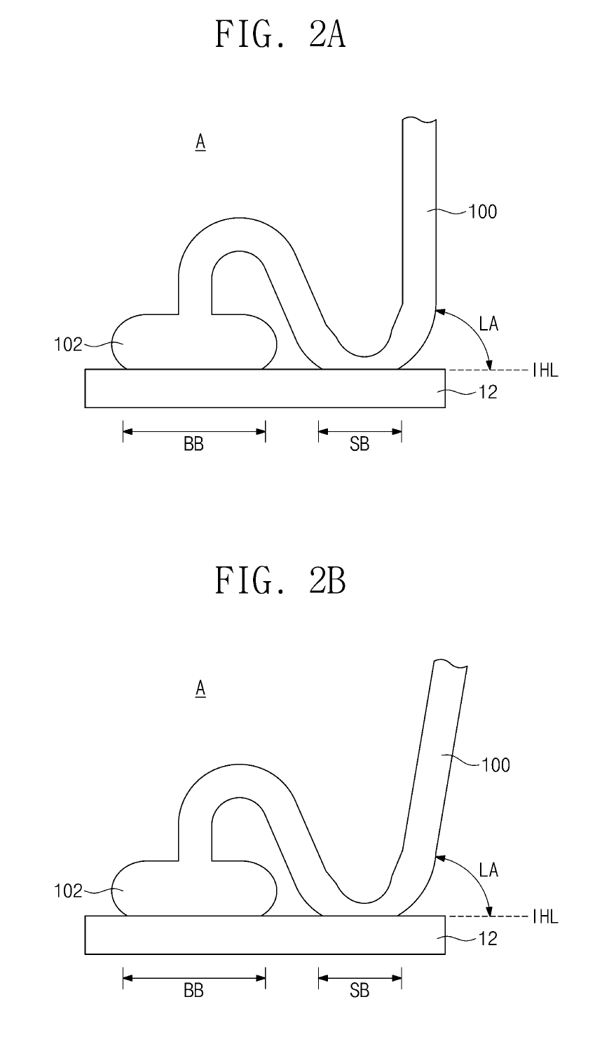

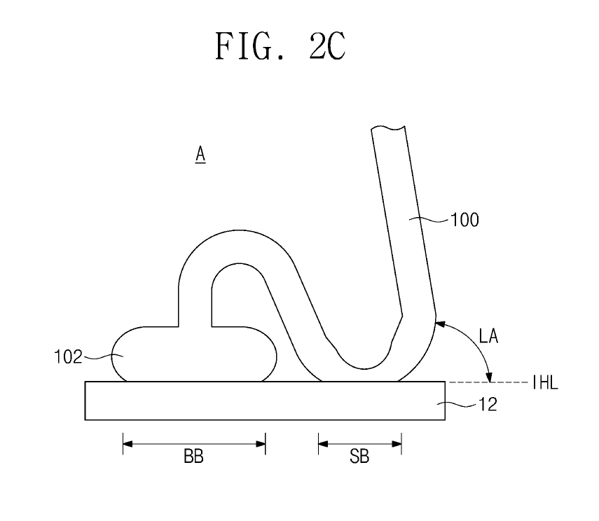

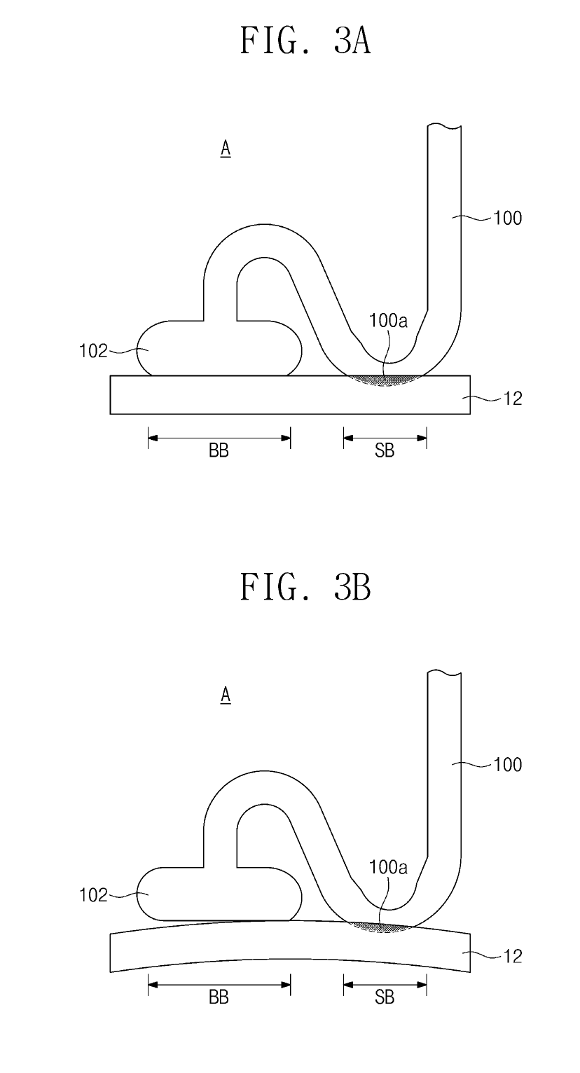

FIGS. 2A to 2C illustrate cross-sectional views showing a first bonding structure A of the semiconductor device 1 depicted in FIG. 1A. FIGS. 3A and 3B illustrate cross-sectional views showing warpage of a first bonding structure A of the semiconductor device depicted in FIG. 1A.

Referring to FIG. 2A, the first bonding structure A may include a ball bonding region BB and a stitch bonding region SB. The ball bonding region BB may be configured such that a ball 102 is coupled to the substrate pad 12 to achieve a ball bonding, and the stitch bonding region SB may be configured such that the bonding wire 100 is coupled to the substrate pad 12 to achieve a stitch bonding.

Though the ball 102 is a portion of the bonding wire 100 including gold (Au) or copper (Cu), the term “ball” is used to distinguish from the term “bonding wire” for convenience of description. The bonding wire 100 extending from the ball 102 may be coupled to the substrate pad 12 while not being in contact with the ball 102. As such, the stitch bonding region SB may be spaced apart from the ball bonding region BB. The stitch bonding region SB may be closer than the ball bonding region BB to the semiconductor chip 20 of FIG. 1A.

The bonding wire 100 extending from the stitch bonding region SB may move upward along a direction away from the substrate pad 12, and then may be coupled to the chip pad 22 of FIG. 1A. The bonding wire 100 may extend at the loop angle LA of about 90° between the substrate pad 12 and the chip pad 22. The loop angle LA may be defined between the bonding wire 100 and an imaginary horizontal line IHL that is parallel to a top surface of the substrate pad 12 or of the package substrate 10. The loop angle LA is not particularly limited. For example, the loop angle LA may be less than 90° as shown in FIG. 2B or greater than 90° as shown in FIG. 2C. As discussed above, the bonding wire 100 may have no limitation in its loop angle LA.

Because the bonding wire 100 may be formed in the reverse loop mode, the bonding wire 100 may move upward without limitation in its loop angle LA and its height. Accordingly, a loop height LH of FIG. 1A may have no limitation. The loop height LH may correspond to a vertical length between top and bottom ends of the bonding wire 100. In this description, the term “vertical” or “vertically” may mean substantially perpendicular to a top surface of the package substrate 10 or of the substrate pad 12, and the term “horizontal” or “horizontally” may mean substantially parallel to the top surface of the package substrate 10 or of the substrate pad 12.

Referring to FIG. 3A, on the stitch bonding region SB, the bonding wire 100 may have an insertion portion 100a that is inserted/ planted into the substrate pad 12. When warpage occurs on the substrate pad 12 or the package substrate 10 of FIG. 1A, the deformation of the substrate pad 12 or the package substrate 10 may act largely on the ball 102 where a contact area of the ball 102 is relatively greater than that of the bonding wire 100. Therefore, a relatively less strain may act on the bonding wire 100. Moreover, because the bonding wire 100 is partially inserted/planted into the substrate pad 12 at the stitch bonding region SB, the stitch bonding may be achieved in addition to the ball bonding region BB.

Referring to FIG. 3B, when warpage occurs on the substrate pad 12 or the package substrate 10, the ball 102 may be at least partially detached from the substrate pad 12 at the ball bonding region BB. Nevertheless, because the bonding wire 100 may have a relatively less strain than that of the ball 102 and the insertion portion 100a may serve as an anchor, the stitch bonding region SB may still maintain a good contact between the bonding wire 100 and the substrate pad 12. Accordingly, the first bonding structure A may retain reliability in mechanical and/or electrical connections. The package substrate 10 may be bent in a direction toward or away from the ball 102.

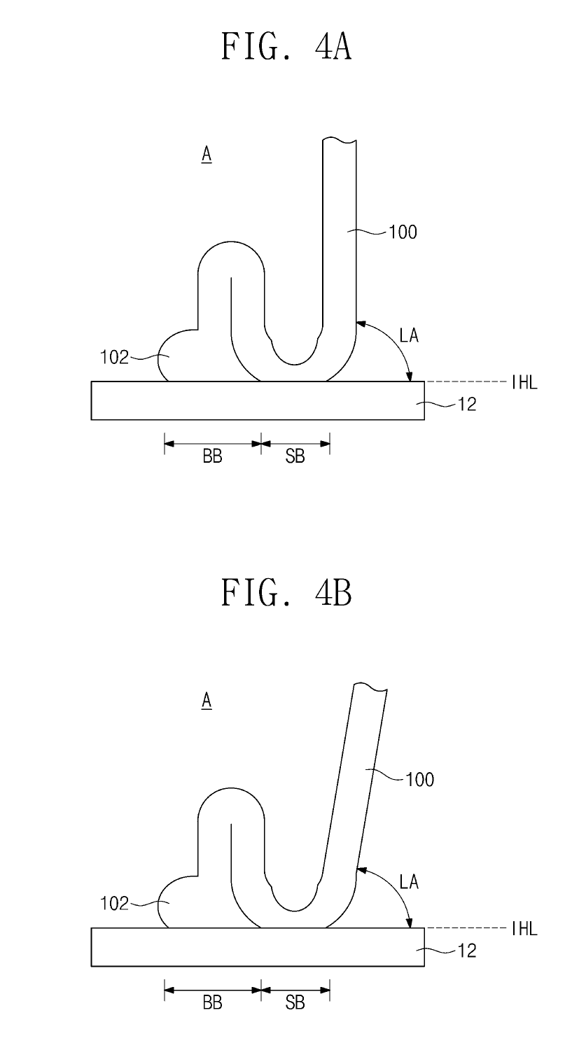

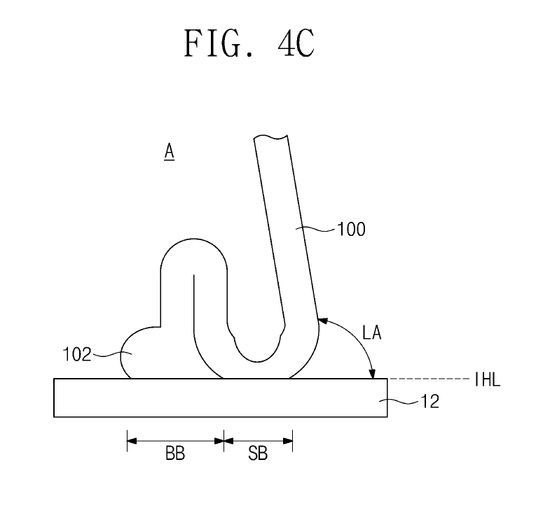

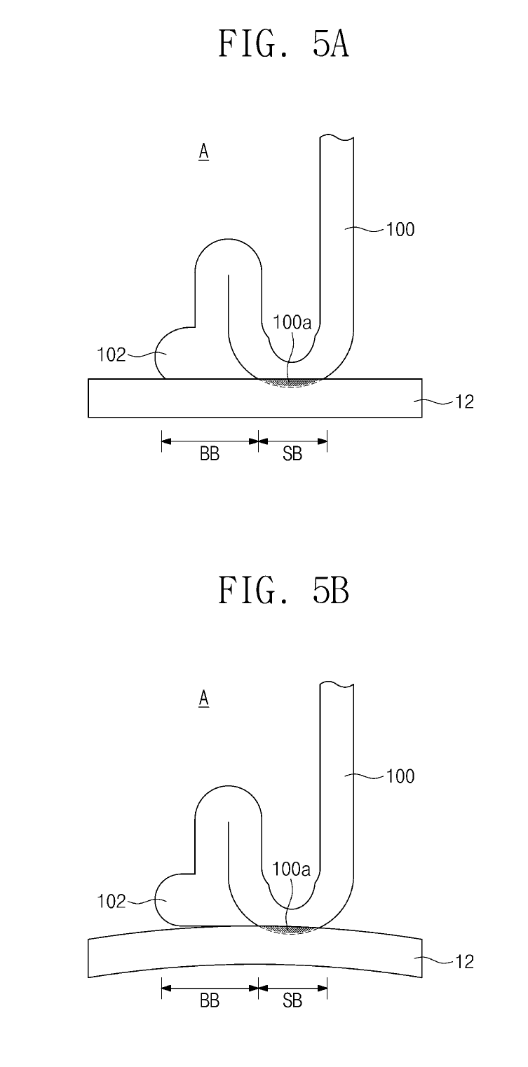

FIGS. 4A to 4C illustrate cross-sectional views showing a first bonding structure A of the semiconductor device 2 depicted in FIG. 1B. FIGS. 5A and 5B illustrate cross-sectional views showing warpage of a first bonding structure A of the semiconductor device 2 depicted in FIG. 1B.

Referring to FIG. 4A, the first bonding structure A may be configured such that the ball bonding region BB and the stitch bonding region SB are not spaced apart from each other. For example, the bonding wire 100 extending from the ball 102 may be coupled to the substrate pad 12 while being in contact with the ball 102. In this sense, the ball 102 may be ball-bonded to the substrate pad 12, and the bonding wire 100 extending from the ball 102 may be stitch-bonded to the substrate pad 12 while being in contact with the ball 102. The bonding wire 100 may extend at the loop angle LA of about 90°. The loop angle LA may be less than 90° as shown in FIG. 4B or greater than 90° as shown in FIG. 4C.

Referring to FIGS. 5A and 5B, on the first bonding structure A including the ball bonding region BB and the stitch bonding region SB that are integrated with each other, the ball bonding region BB may have a defect that the ball 102 and the substrate pad 12 are detached from each other due to warpage of the substrate pad 12 or the package substrate 10. Even when the ball 102 is detached, the first bonding structure A may retain reliability in mechanical and/or electrical connection because the bonding wire 100 has a relatively less strain and/or the insertion portion 100a serves as an anchor, as discussed above with reference to FIGS. 3A and 3B.

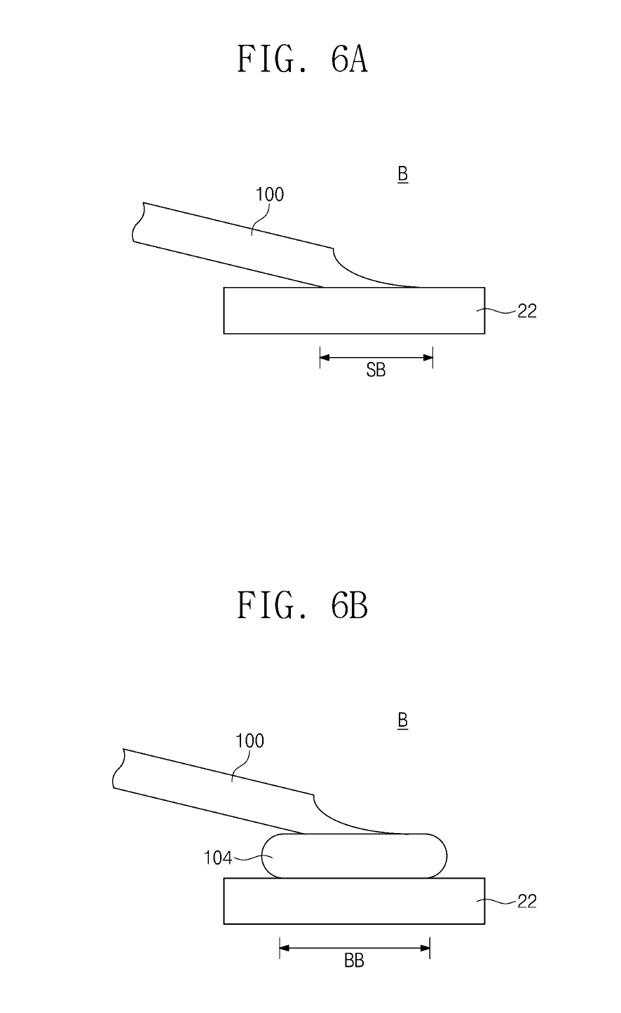

FIG. 6A illustrates a cross-sectional view showing a second bonding structure B of the semiconductor device 1 depicted in FIG. 1A. FIG. 6B illustrates a cross-sectional view showing a second bonding structure B of the semiconductor device 2 depicted in FIG. 1B.

Referring to FIG. 6A, the second bonding structure B of the semiconductor device 1 shown in FIG. 1A may include a stitch bonding region SB. For example, the bonding wire 100 may be stitch-bonded to the chip pad 22. Identical or similar to that discussed above in FIG. 3A, the bonding wire 100 may be partially inserted or planted into the chip pad 22.

Referring to FIG. 6B, the second bonding structure B of the semiconductor device 2 shown in FIG. 1B may include a ball bonding region BB. For example, a ball 104 may further be provided on the chip pad 22, and the bonding wire 100 may be coupled to the ball 104. The bonding wire 100 may be stitch-bonded to and inserted into the ball 104. The ball 104 may be a portion of the bonding wire 100.

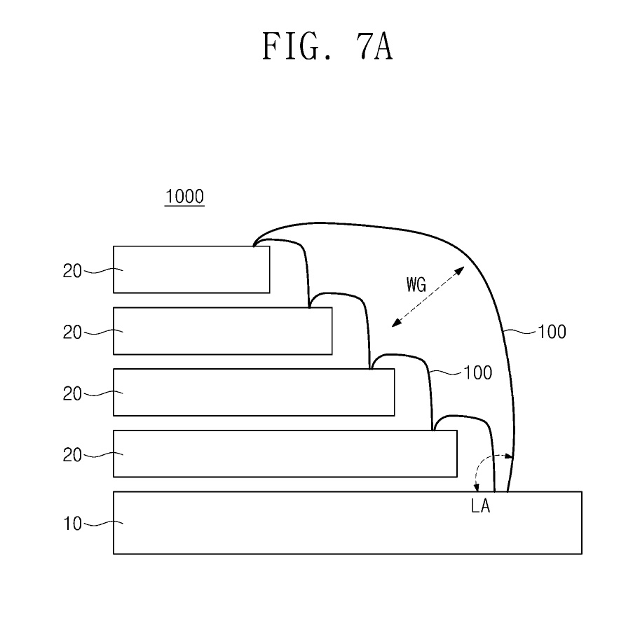

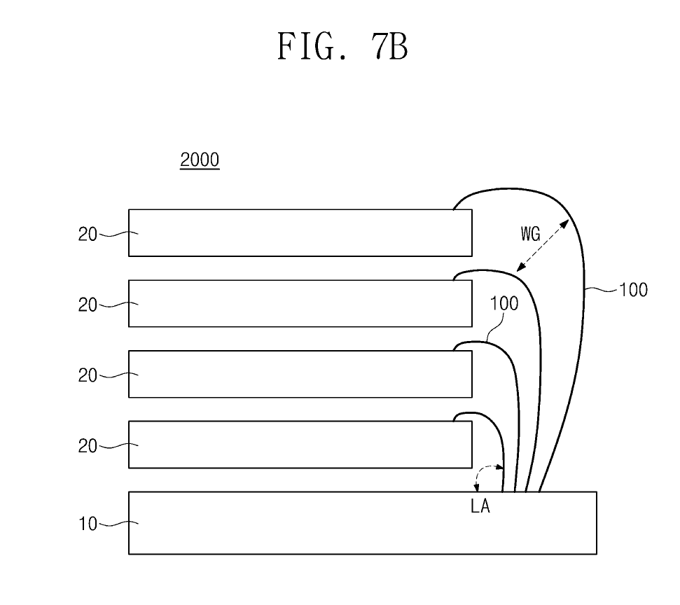

FIGS. 7A and 7B illustrate cross-sectional views showing a semiconductor multichip package according to example embodiments of inventive concepts.

Referring to FIG. 7A, a semiconductor device 1000 may be a semiconductor multichip package including a plurality of the semiconductor chips 20 stepwise stacked on the package substrate 10. The bonding wires 100 may be provided to electrically connect the package substrate 10 to the semiconductor chips 20 and electrically connect the semiconductor chips 20 to one another. As discussed above with reference to FIG. 2A or 3A, because the loop angle LA may have no particular limitation, a wire gap WG may be sufficiently obtained between the bonding wires 100.

Referring to FIG. 7B, a semiconductor device 2000 may be a semiconductor multichip package including a plurality of the semiconductor chips 20 vertically overlapped on the package substrate 10. As discussed above with reference to FIG. 7A, because the loop angle LA may have no limitation, a wire gap WG may be sufficiently obtained between the bonding wires 100.

FIGS. 8A to 8H illustrate cross-sectional views showing a method of fabricating a semiconductor device according to an exemplary embodiment.

Referring to FIG. 8A, there may be provided a semiconductor chip 20, which includes a chip pad 22 and is mounted on a package substrate 10 having a substrate pad 12. The package substrate 10 may be or include a printed circuit board. The semiconductor chip 20 may be or include a memory chip, a logic chip, or a combination thereof. The package substrate 10 may be replaced with an interposer or a semiconductor chip. The semiconductor chip 20 may be replaced with a printed circuit board or an interposer.

A capillary 90 may be provided above the substrate pad 12. A bonding wire 100 may protrude from the capillary 90. The bonding wire 100 may be or may include a conductor such as gold or copper. An electric spark 80 may be applied to the bonding wire 100 protruding from the capillary 90, and the electric spark 80 may melt the protruded bonding wire 100. Thus, a ball 102 may be formed at a bottom end of the capillary 90. A clamp 92 may be closed to allow the capillary 90 to feed the bonding wire 100 equal to or less than a predetermined length.

Referring to FIG. 8B, the capillary 90 may move downward toward the substrate pad 12 with the clamp 92 closed, and then the ball 102 may come into contact with the substrate pad 12. The capillary 90 and the substrate pad 12 may compress the ball 102 therebetween to achieve a ball bonding in which the ball 102 is bonded to the substrate pad 12. Hence, a ball bonding region BB may be formed on the package substrate 10.

Referring to FIG. 8C, the capillary 90 may move upward away from the substrate pad 12 and the ball 102. The clamp 92 may be in an open state. As the capillary 90 moves upward, the bonding wire 100 may vertically extend from the ball 102 bonded to the substrate pad 12.

Referring to FIGS. 8D and 8E, with the clamp 92 being opened, the capillary 90 may move horizontally toward the semiconductor chip 20 and then move downward toward the substrate pad 12, so that the bonding wire 100 may come into contact with the substrate pad 12. As the capillary 90 compresses the bonding wire 100 in contact with the substrate pad 12, the bonding wire 100 may be stitch-bonded to the substrate pad 12. Hence, a stitch bonding region SB may be formed on the package substrate 10.

For example, as illustrated in FIG. 8D, the bonding wire 100 extending from the ball 102 may be stitch-bonded to the substrate pad 12 while not being in contact with the ball 102. Accordingly, the package substrate 10 may be provided thereon with a first bonding structure A in which the ball bonding region BB and the stitch bonding region SB are spaced apart from each other (see FIG. 2A).

For another example, as illustrated in FIG. 8E, the bonding wire 100 extending from the ball 102 may be stitch-bonded to the substrate pad 12 while being in contact with the ball 102. Accordingly, the package substrate 10 may be provided thereon with a first bonding structure A in which the ball bonding region BB and the stitch bonding region SB are not spaced apart from each other (see FIG. 4A).

Hereinafter, it will be described the example embodiment illustrated in FIG. 8D where the ball bonding region BB and the stitch bonding region SB are spaced apart from each other (in a horizontal direction). A description below may be identically or similarly applicable to the example embodiment illustrated in FIG. 8E where the ball bonding region BB and the stitch bonding region SB are not spaced apart from each other.

Referring to FIG. 8F, the capillary 90 may move upward with the clamp 92 being opened. The capillary 90 may move upward to a higher level than that of the chip pad 22. Alternatively, the capillary 90 may move upward to a higher level than that of the chip pad 22, and then move horizontally along a direction away from the chip pad 22. When the capillary 90 moves upward and horizontally, neither mechanical contact nor interference may occur between the capillary 90 and the bonding wire 100 extending from the stitch bonding region SB. Therefore, the capillary 90 may have no limitation in upward and horizontal movement.

Referring to FIG. 8G, with the clamp 92 being opened, the capillary 90 may move horizontally and then downward toward the chip pad 22. As the capillary 90 moves downward, the bonding wire 100 may come into contact with the chip pad 22. As the capillary 90 compresses the bonding wire 100 in contact with the chip pad 22, the bonding wire 100 may be stitch-bonded to the chip pad 22. Hence, the semiconductor chip 20 may be provided thereon with a second bonding structure B having the stitch bonding region SB.

As discussed above with reference to FIG. 8F, the capillary 90 may have no limitation in upward and horizontal movement. When the capillary 90 is properly controlled in its rising height and horizontal moving distance, a loop angle LA and a loop angle LH may be arbitrarily or desirably set up. In this sense, the bonding wire 100 may be obtained in a reverse loop mode in which the bonding wire 100 is formed along a direction from the substrate pad 12 toward the chip pad 22. Accordingly, the bonding wire 100 may not be limited in the loop angle LA and the loop height LH.

Referring to FIG. 8H, with the clamp 92 closed, the capillary 90 may move upward such that the bonding wire 100 within the capillary 90 may be cut from the chip pad 22. Through a series of the processes mentioned above, a semiconductor device 1 of FIG. 1A may be fabricated to include the first bonding structure A having the ball bonding region BB and the stitch bonding region SB mixed on the package substrate 10 and the second bonding structure B having the stitch bonding region BB on the semiconductor chip 20. The first bonding structure A may be configured that the ball bonding region BB and the stitch bonding region SB are spaced apart from each other as illustrated in FIG. 2A or not spaced apart from each other as illustrated in FIG. 4A.

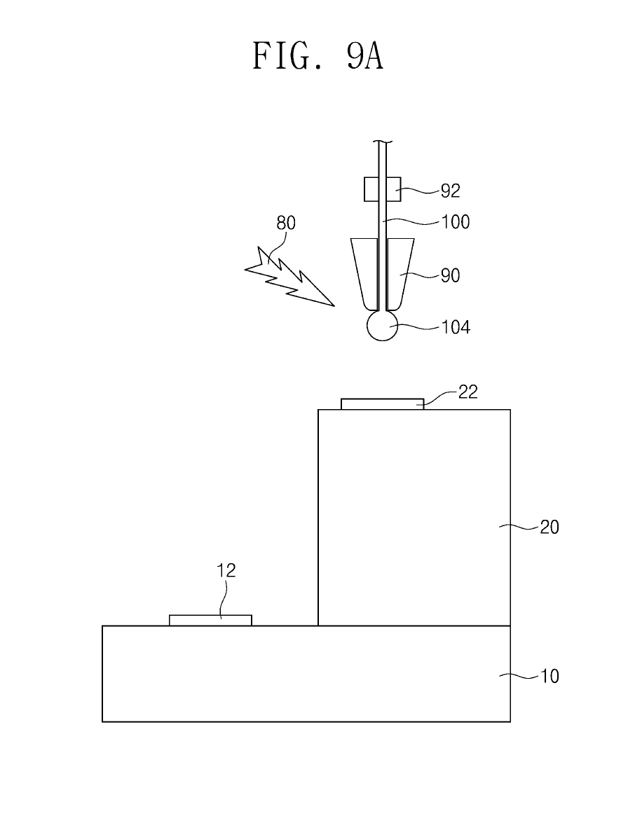

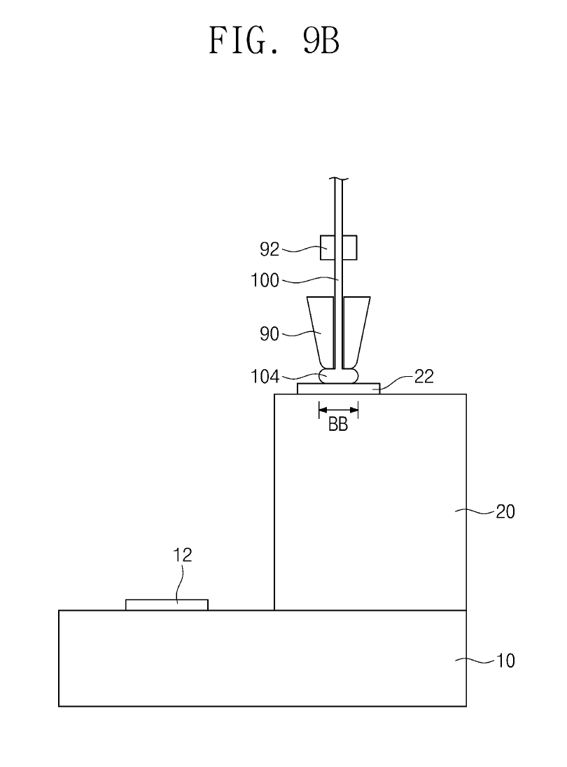

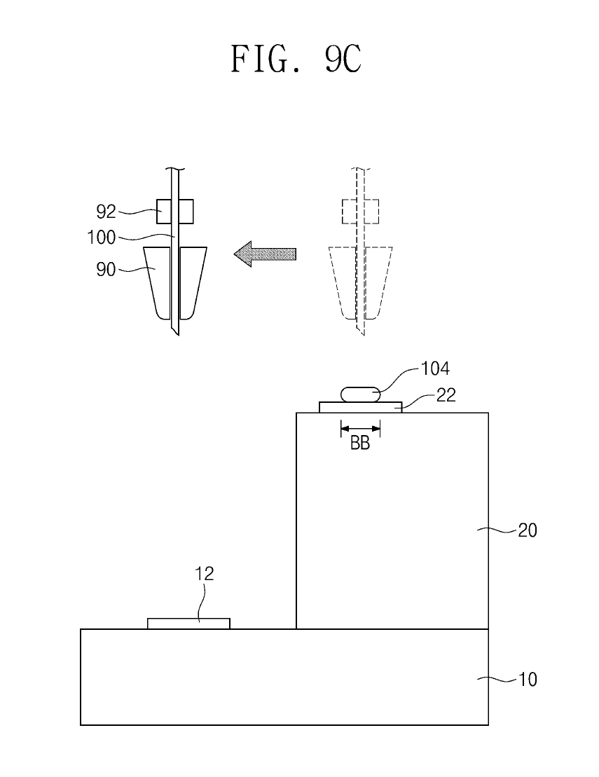

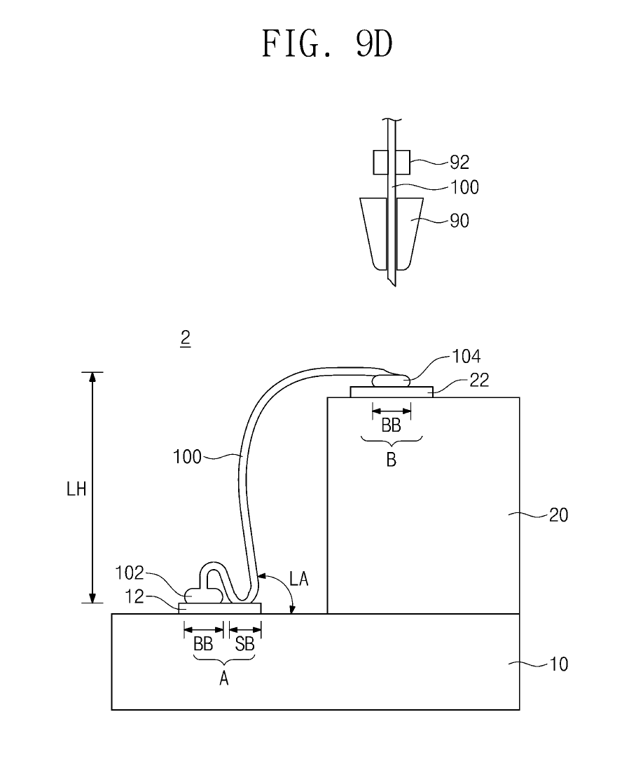

FIGS. 9A to 9D illustrate cross-sectional views showing a method of fabricating a semiconductor device according to an example embodiment. In the example embodiments described below, a repetitive description of those features discussed above with reference to FIGS. 8A to 8H will be omitted or abbreviated for brevity.

Referring to FIG. 9A, the capillary 90 may be placed above the chip pad 22, and the electric spark 80 may be applied to the bonding wire 100. When the electric spark 80 is applied to the bonding wire 100 protruding from the capillary 90, the protruded bonding wire 100 may melt to form the ball 104 at the bottom end of the capillary 90. The clamp 92 may be closed to allow the capillary 90 to feed the bonding wire 100 at equal to or less than a predetermined length.

Referring to FIG. 9B, with the clamp 92 being closed, the capillary 90 may move downward toward the chip pad 22, and then the ball 104 may come into contact with the chip pad 22. The capillary 90 and the chip pad 22 may compress the ball 104 therebetween to achieve a ball bonding in which the ball 104 is bonded to the chip pad 22. Hence, the ball bonding region BB may be formed on the semiconductor chip 20.

Referring to FIG. 9C, the capillary 90 may move upward away from the chip pad 22. The clamp 92 may remain in a closed state. As the capillary 90 moves upward, the bonding wire 100 may be cut from the ball 104 bonded to the chip pad 22. Afterwards, the capillary 90 may move horizontally toward the substrate pad 12, and then a series of the processes discussed above with reference to FIGS. 8A to 8H may be performed.

Referring to FIG. 9D, through a series of the processes mentioned above, a semiconductor device 2 of FIG. 1B may be fabricated to include a first bonding structure A having the ball bonding region BB and the stitch bonding region SB mixed on the package substrate 10 and a second bonding structure B having the ball bonding region BB on the semiconductor chip 20.

The first bonding structure A may be configured such that the ball bonding region BB and the stitch bonding region SB are spaced apart from each other as illustrated in FIG. 2A or not spaced apart from each other as illustrated in FIG. 4A. The second bonding structure B may be configured that the bonding wire 100 is stitch-bonded to the ball 104.

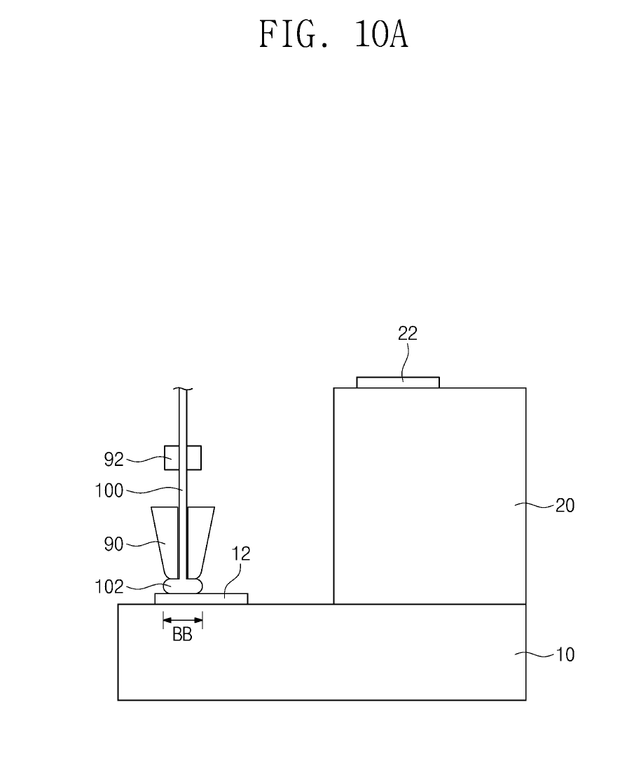

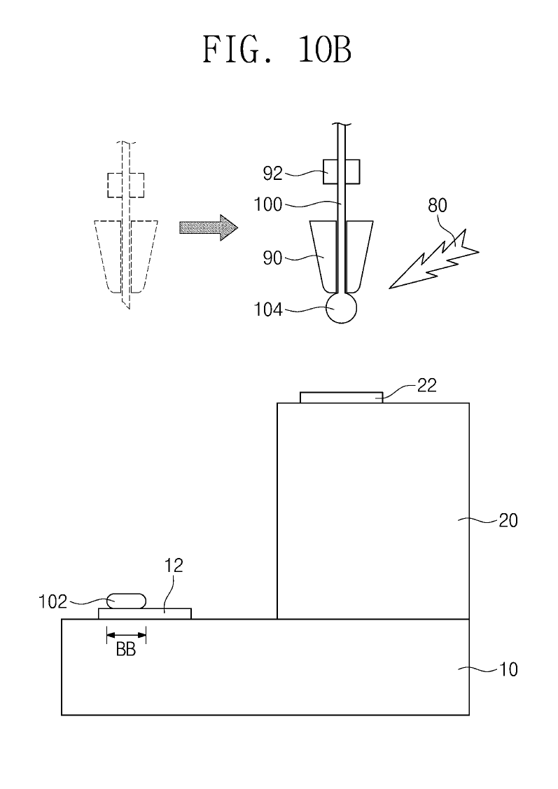

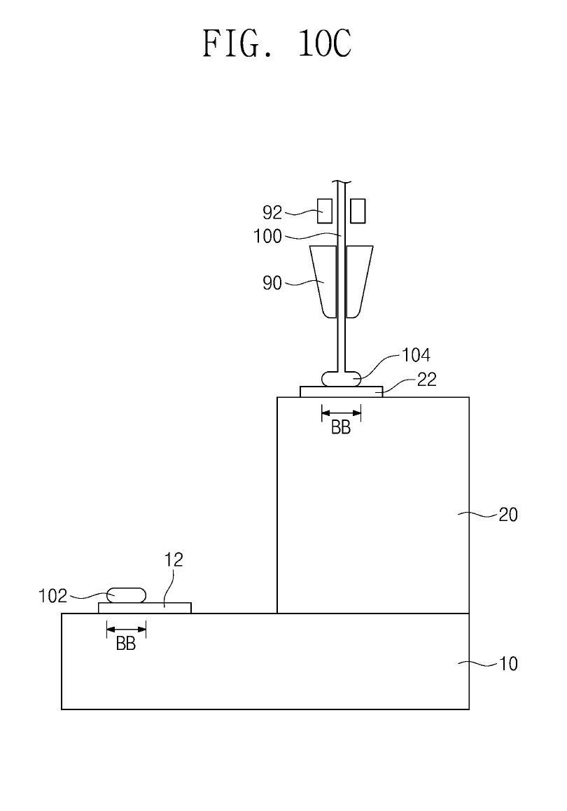

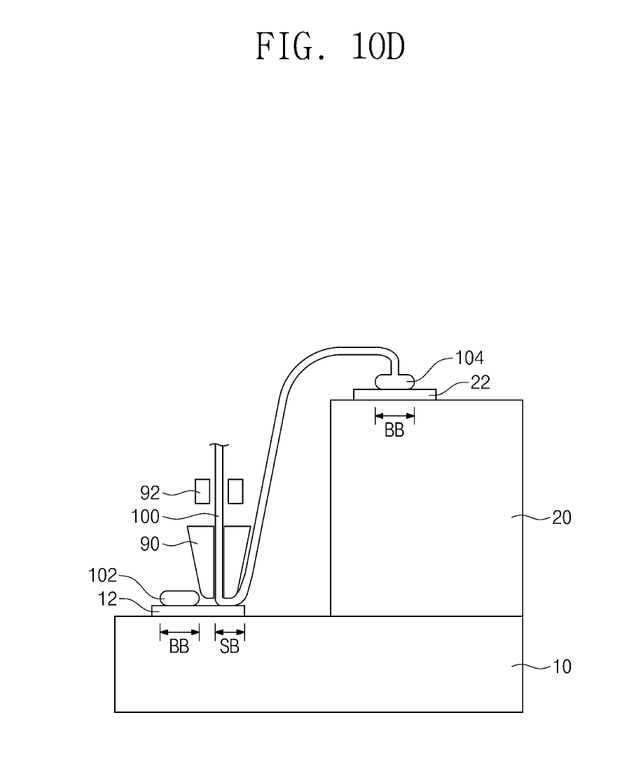

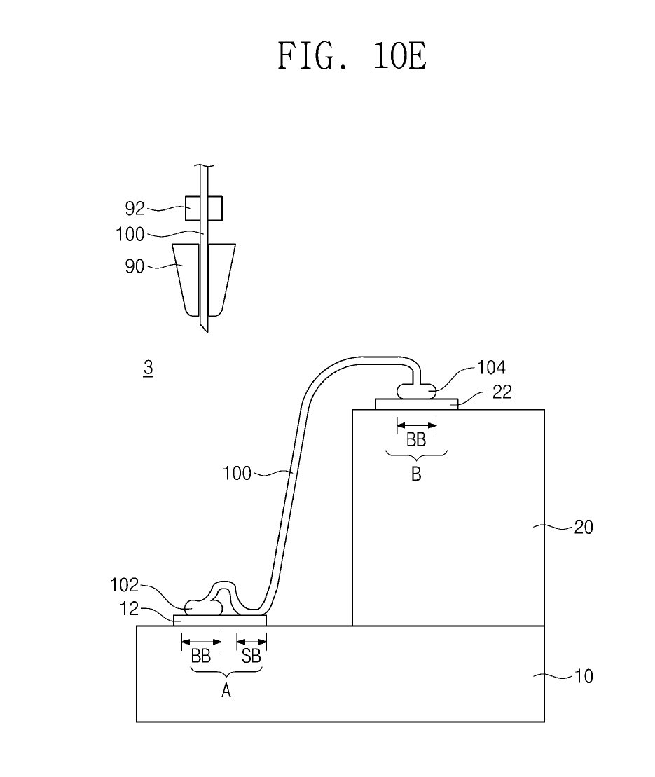

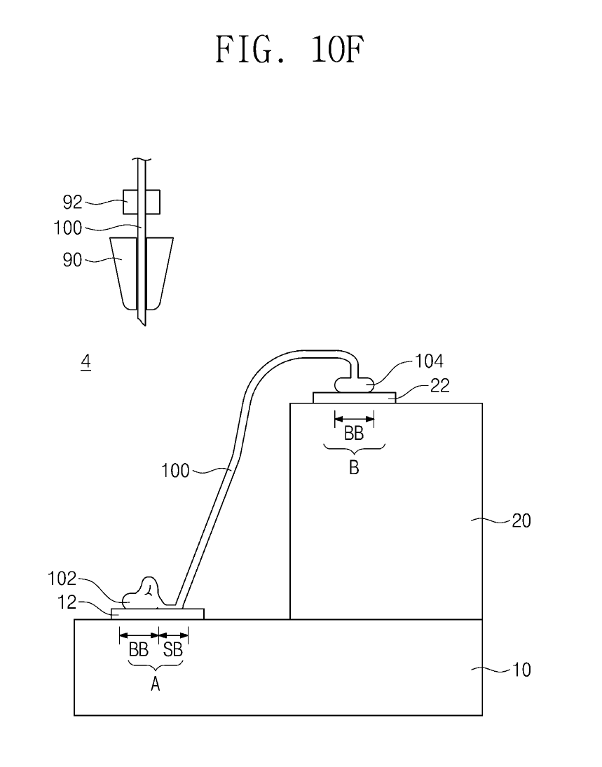

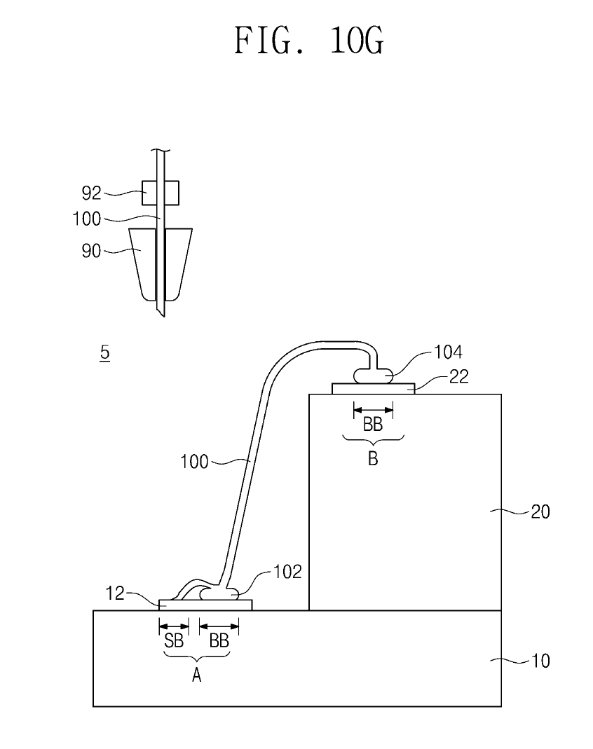

FIGS. 10A to 10G illustrate cross-sectional views showing a method of fabricating a semiconductor device according to an exemplary embodiment.

Referring to FIG. 10A, processes may be performed identically or similarly to those discussed above with reference to FIGS. 8A and 8B. Through these processes, the ball 102 may be attached to the substrate pad 12, and thus the ball bonding region BB may be formed on the package substrate 10.

Referring to FIG. 10B, the capillary 90 may move upward away from the substrate pad 12 with the clamp 92 being closed, with the result that the bonding wire 100 may be cut from the ball 102. Thereafter, the capillary 90 may be placed above the chip pad 22, and then the bonding wire 100 protruding from the capillary 90 may be supplied with the electric spark 80 to form the ball 104.

Referring to FIG. 10C, with the clamp 92 being closed, the capillary 90 may move downward toward the chip pad 22, and then the ball 104 may come into contact with the chip pad 22. The capillary 90 and the chip pad 22 may compress the ball 104 therebetween to achieve a ball bonding in which the ball 104 is bonded to the chip pad 22. Hence, the ball bonding region BB may be formed on the semiconductor chip 20. When the ball bonding is achieved, the capillary 90 may move upward with the clamp 92 opened.

Referring to FIG. 10D, the raised capillary 90 may move horizontally and then downward toward the substrate pad 12. The bonding wire 100 extending from the ball 104 bonded to the chip pad 22 may be stitch-bonded to the substrate pad 12 while not being in contact with the ball 102 bonded to the substrate pad 12. Hence, the stitch bonding region SB may be formed on the package substrate 10 on which the ball bonding region BB is formed.

Referring to FIG. 10E, the capillary 90 may move to couple the bonding wire 100 to the ball 102. After the bonding wire 100 is coupled to the ball 102, the capillary 90 may move upward away from the substrate pad 12 so that the bonding wire 100 within the capillary 90 may be cut from the ball 102. Accordingly, a semiconductor device 3 may be fabricated to include a first bonding structure A having the ball bonding region BB and the stitch bonding region SB spaced apart from each other on the package substrate 10 and a second bonding structure B having the ball bonding region BB on the semiconductor chip 20. The first bonding structure A may be configured such that the stitch bonding region SB is closer than the ball bonding region BB to the semiconductor chip 20.

Alternatively, referring to FIG. 10F, when the stitch bonding region SB is formed as discussed above with reference to FIG. 10D, the bonding wire 100 may be stitch-bonded to the substrate pad 12 while being in contact with the ball 102 boned to the substrate pad 12. Accordingly, a semiconductor device 4 may be fabricated to include a first bonding structure A having the ball bonding region BB and the stitch bonding region SB that are not spaced apart from each other on the package substrate 10 and a second bonding structure B having the ball bonding region BB on the semiconductor chip 20.

Alternatively, referring to FIG. 10G, the bonding wire 100 that has extended from the ball bonding region BB on the semiconductor chip 20 may come into contact with the ball 102 bonded to the substrate pad 12. Thereafter, the bonding wire 100 may extend from the ball 102, and then may be stitch-bonded to the substrate pad 12. Accordingly, a semiconductor device 5 may be fabricated to include a first bonding structure A having the ball bonding region BB and the stitch bonding region SB that are spaced apart from each other on the package substrate 10 and a second bonding structure B having the ball bonding region BB on the semiconductor chip 20.

Alternatively, similar to that shown in FIG. 10F, the first bonding structure A may be configured that the ball bonding region BB and the stitch bonding region SB are not spaced apart from each other. On the first bonding structure A of the semiconductor device 5, the ball bonding region BB may be closer than the stitch bonding region SB to the semiconductor chip 20.

The semiconductor devices 3, 4, and 5 of FIGS. 10E to 10G may be configured similarly to the semiconductor device 2 of FIG. 1B. Differently from the semiconductor device 2, the bonding wire 100 of each of the semiconductor devices 3, 4, and 5 may be obtained in a forward loop mode in which the bonding wire 100 is formed along a direction from the chip pad 22 at a higher level toward the substrate pad 12 at a lower level.

According to inventive concepts discussed above, the bonding wire may be firstly ball-bonded and secondly stitch-bonded to the bonding pad. Even when the ball bonding fails or breaks due to warpage or stress on the substrate, the stitch bonding may still maintain an electrical connection between the bonding pad and the bonding wire. The wire bonding may therefore increase reliability in mechanical and/or electrical connection, and as a result, a semiconductor device may increase mechanical and/or electrical reliability and characteristics.

This detailed description of inventive concepts should not be construed as limited to the example embodiments set forth herein, and it is intended that inventive concepts cover the various combinations, the modifications and variations of this invention without departing from the spirit and scope of inventive concepts. The appended claims should be construed to include other embodiments.

1. A semiconductor device, comprising:
a first device having a first pad;
a second device having a second pad; and
a bonding wire electrically connecting the first device and the second device to each other via the first pad and the second pad,
wherein the bonding wire comprises:
a first bonding structure provided at a first end of the bonding wire, electrically connected to the first device and comprising:
a first ball bonding region; and
a first stitch bonding region; and
a second bonding structure provided at a second end opposite of the first end of the bonding wire and electrically connected to the second device.

2. The semiconductor device of claim 1, wherein the first ball bonding region and the first stitch bonding region are spaced apart from each other.

3. The semiconductor device of claim 1, wherein the first ball bonding region and the first stitch bonding region are in contact with each other.

4. The semiconductor device of claim 1, wherein the second bonding structure comprises one of a second ball bonding region and a second stitch bonding region.

5. The semiconductor device of claim 1, wherein the first stitch bonding region is closer to the second device than the first ball bonding region.

6. The semiconductor device of claim 1, wherein the second device is provided on the first device and the first pad is exposed without being covered by the second device.

7. The semiconductor device of claim 1, wherein the bonding wire extends from the first pad toward the second pad at a loop angle of 90° or more, and
wherein the loop angle is defined as an angle between the first pad and the bonding wire extending from the first stitch bonding region.

8. A semiconductor device, comprising:
a substrate comprising a substrate pad;
a semiconductor chip mounted on the substrate and comprising a chip pad; and
a bonding wire having a first end being connected to the substrate pad and a second end opposite to the first end being connected to the chip pad,
wherein the first end of the bonding wire comprises a substrate bonding structure, the substrate bonding structure comprising:
a first ball bonding region in which a first conductive ball is connected to the substrate pad; and
a first stitch bonding region in which the bonding wire extends from the first conductive ball and is partially inserted into the substrate pad, and
wherein the second end of the bonding wire comprises a chip bonding structure in which the bonding wire extends from the first stitch bonding region to come into electrical connection with the chip pad.

9. The semiconductor device of claim 8, wherein the chip bonding structure comprises a second stitch bonding region in which the bonding wire extending from the first stitch bonding region of the substrate bonding structure is partially inserted in the chip pad.

10. The semiconductor device of claim 8, wherein the chip bonding structure comprises a second ball bonding region in which the bonding wire extending from the first stitch bonding region is connected to a second conducive ball bonded to the chip pad.

11. The semiconductor device of claim 8, wherein the first ball bonding region and the first stitch bonding region are spaced apart from each other on the substrate pad.

12. The semiconductor device of claim 8, wherein the first ball bonding region and the first stitch bonding region are in contact with each other on the substrate pad.

13. The semiconductor device of claim 8, wherein the first stitch bonding region is closer to the chip pad than the first ball bonding region.

14. The semiconductor device of claim 8, wherein the bonding wire extends from the first conductive ball of the first ball bonding region and is connected to the substrate pad of the first stitch bonding region, and further extends from the first stitch bonding region toward the chip pad.

15. The semiconductor device of claim 14, wherein the bonding wire extends at a loop angle between an extending direction of the bonding wire and a top surface of the substrate, and
wherein the loop angle is greater than or equal to 90°.

16.-23. (canceled)

24. A semiconductor device, comprising:
a substrate comprising a first pad provided on the substrate;
a chip provided on the substrate having a second pad provided on the chip; and
a bonding wire connecting the substrate and the chip to each other via the first pad and the second pad,
wherein the bonding wire comprises:
a first bonding portion provided at a first end of the bonding wire and electrically connected to the substrate and comprising:
a first bonding region; and
a second bonding region; and
a second bonding portion provided at a second end opposite of the first end of the bonding wire and electrically connected to the chip,
wherein in the first bonding region, the bonding wire is ball-bonded to the substrate, and
wherein in the second bonding region, the bonding wire is stitched to the substrate.

25. The semiconductor device of claim 24, wherein the first bonding region and the second bonding region are spaced apart from each other.

26. The semiconductor device of claim 24, wherein the first bonding region and the second bonding region are in contact with each other.
